(19) United States
(12) Patent Application Publication
(10) Pub. No.: US 2024/0345133 A1
(43) Pub. Date: Oct. 17, 2024

(54) Roller Tap Down Technique for Probe Arrays

(71) Applicant: FormFactor, Inc., Livermore, CA (US)

(72) Inventors: Sterling Tadashi Collins, Oakland, CA (US); Vinh-Lam Olivier Buu, Burlingame, CA (US); Kevin John Hughes, Jurupa Valley, CA (US)

(21) Appl. No.: 18/634,655

(22) Filed: Apr. 12, 2024

Related U.S. Application Data
(60) Provisional application No. 63/458,923, filed on Apr. 12, 2023.

(51) Int. Cl. G01R 1/073

(52) U.S. Cl. CPC G01R 1/07314

(57) ABSTRACT

A roller mechanism with controlled height is used for probe tap-down in arrays of vertical probes for device testing. The height can be controlled using features of the roller, or external shims. This approach overcomes issues related to guide plate flexure during plate tap down by reducing forces on guide plates. It also avoids issues of probe damage from manual tap down.

### CROSS REFERENCE TO RELATED APPLICATIONS

This application claims priority from U.S. Provisional Patent Application 63/458,923 filed Apr. 12, 2023, which is incorporated herein by reference.

### GOVERNMENT SPONSORSHIP

None.

### FIELD OF THE INVENTION

This invention relates to testing electrical devices using probe arrays.

### BACKGROUND

Probe arrays are often used to make temporary electrical contact to a wafer, circuit or device under test. In vertical probe arrays, the probes are configured as flexible members that pass through upper and lower guide plates. The guide plates thus define the contact pattern made by the probe array.

As technology evolves, there is a need for an ever-increasing number of probes in vertical probe arrays. This evolution can create new problems for making such probe arrays. One such problem is a difficulty in getting all the probes vertically aligned with each other (so that the probe tips are coplanar).

One simple approach for performing this alignment is to have the probe array make contact with a flat plate on the tip ends of all probes. This idea is referred to as “plate tap-down”. For probe arrays with a large number of probes, plate tap-down can fail if the upper guide plate deforms instead of the probes moving through the upper guide plate to become properly aligned. This can be understood by each probe needing a certain force to get pushed up or down in the array, and the guide plate will undesirably bend if (the number of probes) x (force per probe) is enough to bend the guide plate. Thus, large, unsupported guide plates flex during tap-down which prevents the probes from being properly seated.

This problem is shown on FIG. 1. Here the top part shows probe array 104, upper guide plate 106 and lower guide plate 108. As shown here, the probes are vertically misaligned, and it is desired they be made coplanar, so that all probes make electrical contact to space transformer 102 and all probe tips are coplanar. Since the probes can be fabricated to have equal lengths to a high tolerance, these two conditions are equivalent. The lower two panels of FIG. 1 shows how plate tap down can fail. If the upper guide plate 106 flexes during the plate tap down using plate 110 (middle panel), then after plate 110 is removed, guide plate 106 returns to its usual position, thereby misaligning the probes (bottom panel).

Alternative manual methods for this probe alignment are exceedingly tedious and pose a high risk of damage to the probe array. For example, using a flexible shim with a brush and manual action leads to nonuniform results and has a high risk of damage to probe tips. FIG. 2 illustrates this problem. Here 202 is the flexible shim and 204 is the brush. The top panel shows applying force with the brush to align probes, and the bottom panel shows the poor alignment results typical of this method. Note that the probe array on FIG. 2 (and the following figures) is flipped vertically compared to how it is shown on FIG. 1.

Accordingly, it would be an advance in the art to provide improved alignment of probes in probe arrays.

### SUMMARY

In this work, a roller-mechanism with controlled height is used for probe tap-down. This approach successfully seats probes, even on large, high-probe count arrays with large unsupported guide plates, which the previous plate method does not. It is faster and poses a lower risk of accidental damage to the probes than the flexible shim method.

FFP-566/US 3

### BRIEF DESCRIPTION OF THE DRAWINGS

FIG. 1 shows a first prior art method of probe alignment.

FIG. 2 shows a second prior art method of probe alignment.

FIGS. 3A-B show a first embodiment of the invention.

FIGS. 4A-B show a second embodiment of the invention.

FIGS. 5-7 show probe alignment results obtained using embodiments of the invention.

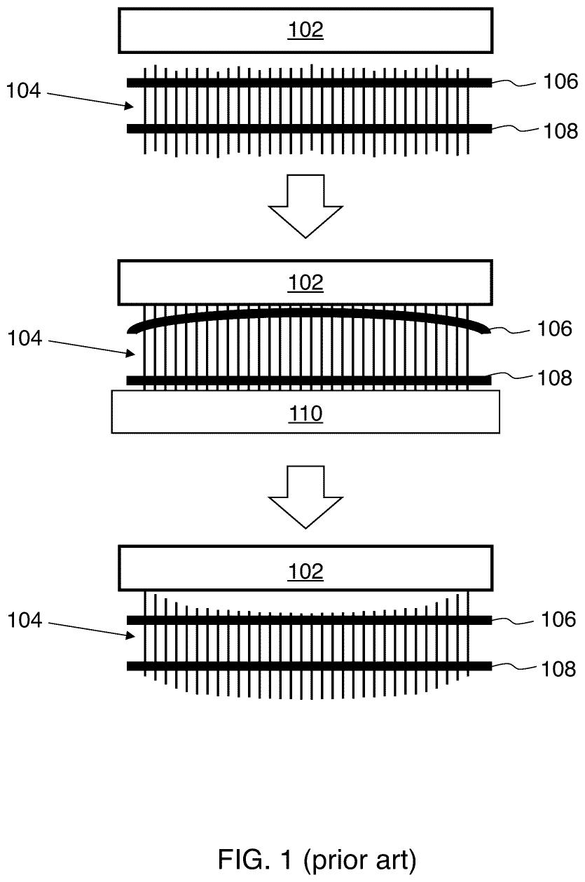

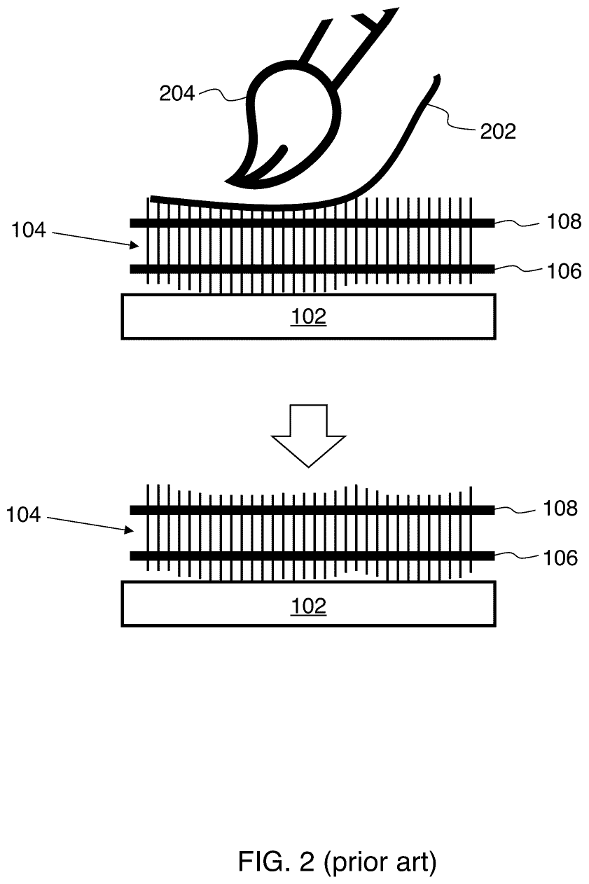

### DETAILED DESCRIPTION

An exemplary embodiment of the invention is a method of aligning probes in a vertical probe array having the following steps:
disposing two or more vertical probes in a probe head including an upper guide plate and a lower guide plate, where each probe passes through corresponding holes in the upper and lower guide plates; and
aligning the vertical probes by making mechanical contact between tips of the two or more vertical probes and a roller as the roller is rolled over the vertical probe array at a predetermined vertical distance from the lower guide plate.

This method is expected to be especially advantageous in connection with large probe arrays (e.g., 100 probes or more, 1,000 probes or more, even 10,000 probes or more). Guide plate flexure is eliminating by providing force to the probes one row at a time, instead of to all probes in the probe array simultaneously. This advantage may also be realized in rolling configurations where force is simultaneously applied to a small number of rows in the probe array, so practice of the invention should not be construed as strictly requiring “one row at a time” application of alignment forces.

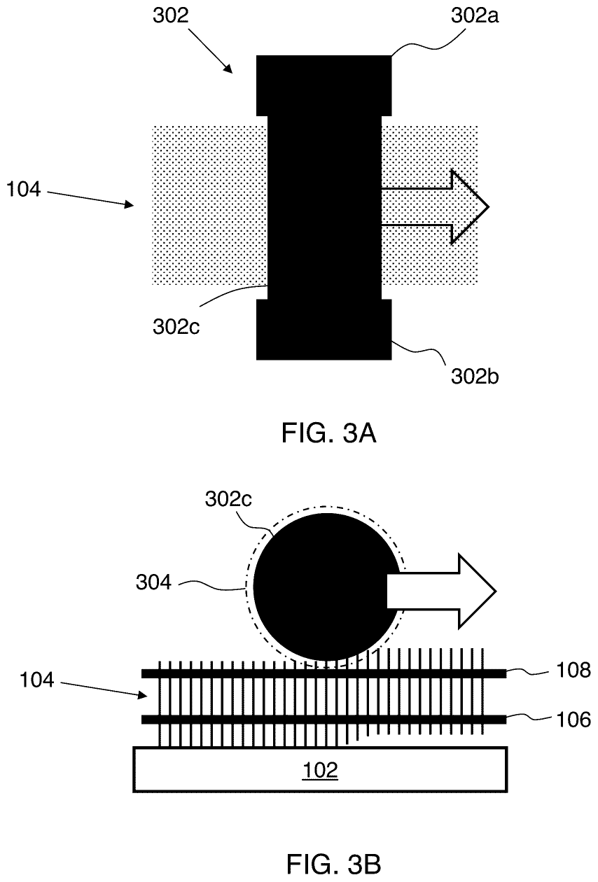

The predetermined vertical distance can be determined by mechanical features of the roller. FIGS. 3A-B show top (FIG. 3A) and side (FIG. 3B) views of an embodiment of the invention having this approach for defining the predetermined vertical distance. Here roller 302 has three co-axial sections 302a, 302b, and 302c along its length, with sections 302a and 302c sandwiching section 302b along the length of the roller. Radiuses of sections 302a, 302b, 302c are r_{A}, r_{B}, r_{C}, respectively. Sections 302a, and 302c have the same radius (r_{A}=r_{C}), and section 302b has a smaller radius (r_{A}>r_{B}), so the predetermined vertical distance is the difference in radius (r_{A}−r_{B}). In the side view of FIG. 3B, dashed line 304 represents the side view of the larger roller sections 302a,b. Here the probes are uniformly and consistently displaced in a controlled manner.

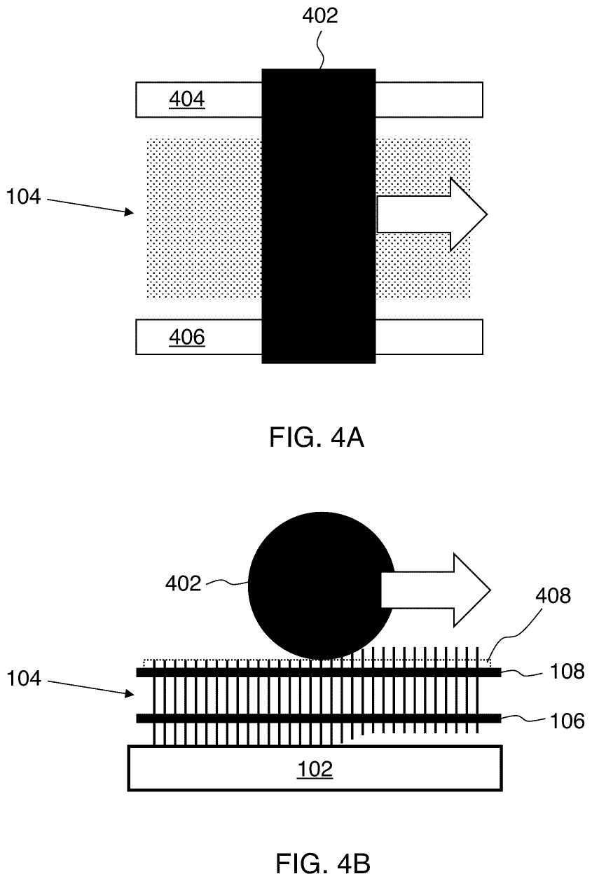

Alternatively, the predetermined vertical distance can be defined by a shim disposed between the probe array and the roller. FIGS. 4A-B show top (FIG. 4A) and side (FIG. 4B) views of an embodiment of the invention having this approach for defining the predetermined vertical distance. Here the shim is configured as two members (404 and 406 on FIG. 4A) having a thickness equal to the predetermined vertical distance (shown as 408 on FIG. 4B). The two members 404 and 406 are disposed on the lower guide plate to sandwich the vertical probe array 104 in a direction perpendicular to a motion direction of roller 402 over the vertical probe array, as shown on FIG. 4A. Here also, the probes are uniformly and consistently displaced in a controlled manner.

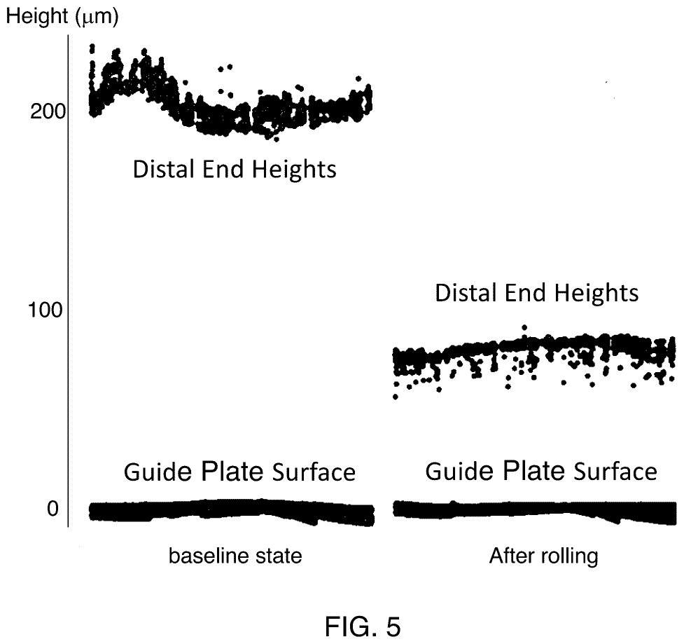

FIG. 5 shows an example of roller probe alignment according to the embodiment of FIGS. 3A-B. The baseline is before any alignment is done, and the ‘after rolling’ result is after rolling using a stepped-radius roller designed to have the predetermined vertical distance be 3 mils (a mil is 0.001 inch, which is about 25 microns). Here and on the following figures, “distal end” is a synonym for probe tip.

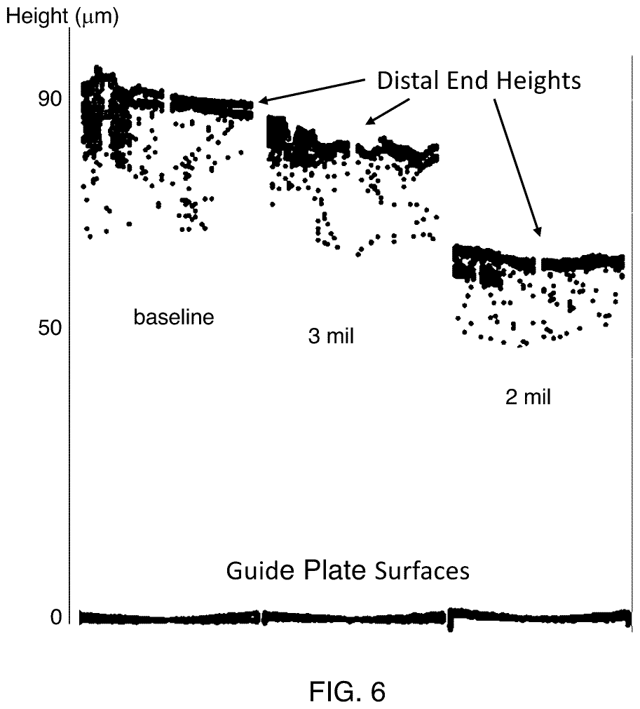

FIG. 6 shows an example of roller probe alignment according to the embodiment of FIGS. 4A-B on a probe array with 2,000 probes. The baseline is before any alignment is done, and the ‘3 mil’ and ‘2 mil’ results are after rolling first using 3 mil shims and then using 2 mil shims. After the 2 mil rolling, probe tips were visually inspected and there was no detectable damage. The roller was a 0.375″ diameter stainless steel rod, and the shim strips were plastic.

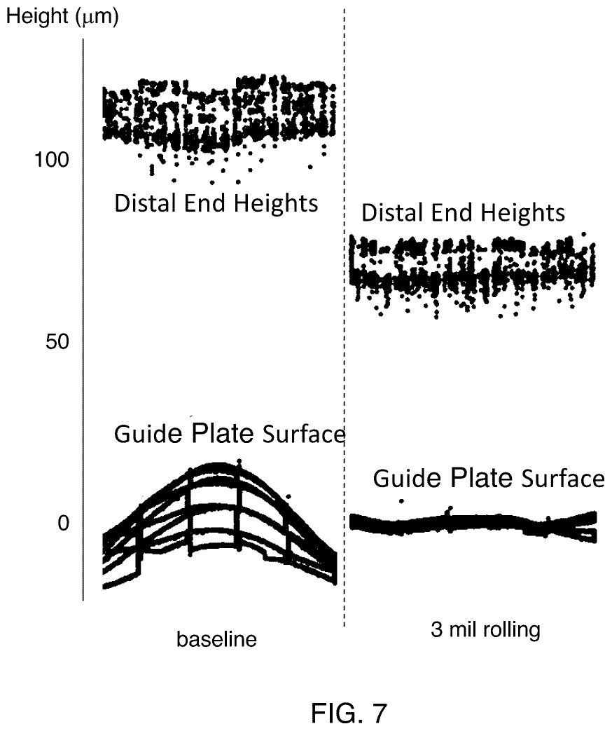

FIG. 7 shows another example of roller probe alignment according to the embodiment of FIGS. 4A-B, this time on a probe array with 22,000 probes. The baseline is before any alignment is done, and the ‘3 mil’ result is after rolling using 3 mil shims, respectively. Note that the baseline in this example undesirably has a flexed guide plate, and this issue is also removed by this probe alignment method. After the rolling, probe tips and guide plates were visually inspected and there was no detectable damage. The roller was a 0.375″ diameter stainless steel rod, and the shim strips were plastic. Practice of the invention does not depend critically on the materials of the roller and shims (if present). For the roller, any material suitable for exerting force on probe tips without damaging them can be used. For the shims, any material that accurately defines the predetermined vertical distance can be used.

The preceding description has focused on probe alignment problems caused by flexing of the upper guide plate. In case there are situations where flexing of the lower guide plate causes similar problems, it is expected that embodiments of the invention will also alleviate any such problems.

1. A method of aligning probes in a vertical probe array, the method comprising:
disposing two or more vertical probes in a probe head including an upper guide plate, and a lower guide plate, wherein each of the two or more vertical probes passes through corresponding holes in the upper and lower guide plates;
aligning the vertical probes by making mechanical contact between tips of the two or more vertical probes and a roller as the roller is rolled over the vertical probe array at a predetermined vertical distance from the lower guide plate.

2. The method of claim 1, wherein the predetermined vertical distance is defined by a shim disposed between the probe array and the roller.

3. The method of claim 2, wherein the shim is configured as two members having a thickness equal to the predetermined vertical distance, and wherein the two members are disposed on the lower guide plate to sandwich the vertical probe array in a direction perpendicular to a direction of roller motion over the vertical probe array.

4. The method of claim 1, wherein the predetermined vertical distance is determined by mechanical features of the roller.

5. The method of claim 4, wherein the roller has three co-axial sections A, B, C along its length, with sections A and C sandwiching section B along the length of the roller, wherein radiuses of sections A, B, C are r_{A}, r_{B}, r_{C}, respectively, wherein r_{A}=r_{C}, wherein r_{A}>r_{B}, and wherein the predetermined vertical distance is r_{A}−r_{B}.

6. The method of claim 1, wherein the two or more probes comprise 1,000 or more probes.

7. The method of claim 4, wherein the 100 or more probes comprise 10,000 or more probes.
